(19) United States
(12) Patent Application Publication
(10) Pub. No.: US 2011/0309376 A1
(43) Pub. Date: Dec. 22, 2011

(54) METHOD OF CLEANING SILICON CARBIDE SEMICONDUCTOR, SILICON CARBIDE SEMICONDUCTOR, AND SILICON CARBIDE SEMICONDUCTOR DEVICE

(75) Inventors: Toru HIYOSHI, Osaka-shi (JP); Keiji WADA, Osaka-shi (JP); Takeyoshi MASUDA, Osaka-shi (JP); Hiromu SHIOMI, Osaka-shi (JP); Satomi ITOH, Osaka-shi (JP); Tomihito MIYAZAKI, Osaka-shi (JP)

(73) Assignee: SUMITOMO ELECTRIC INDUSTRIES, LTD., Osaka-shi (JP)

(21) Appl. No.: 13/102,660

(22) Filed: May 6, 2011

(30) Foreign Application Priority Data
Jun. 16, 2010 (JP) 2010-136867

(51) Int. Cl. H01L 29/161; H01L 21/306

(52) U.S. Cl. 257/77; 438/694; 257/E29.084; 257/E21.224

(57) ABSTRACT

A method of cleaning an SiC semiconductor capable of exhibiting an effect of cleaning an SiC semiconductor is provided. An SiC semiconductor and an SiC semiconductor device capable of achieving improved characteristics are provided. The method of cleaning an SiC semiconductor includes the steps of forming an oxide film on a surface of an SiC semiconductor (step S2) and removing the oxide film (step S3). In the forming step (step S2), the oxide film is formed in a dry atmosphere at a temperature not lower than 700° C. that contains O element. The SiC semiconductor is an SiC semiconductor having a surface and the surface has metal surface density not higher than 1×10¹² cm⁻². The SiC semiconductor device includes an SiC semiconductor and an oxide film formed on a surface of the SiC semiconductor.

### BACKGROUND OF THE INVENTION

1. Field of the Invention

The present invention relates to a method of cleaning a silicon carbide (SiC) semiconductor, an SiC semiconductor, and an SiC semiconductor device, and more particularly to a method of cleaning an SiC semiconductor used for a semiconductor device having an oxide film, an SiC semiconductor, and an SiC semiconductor device.

2. Description of the Background Art

In order to remove deposits adhering to a surface of a semiconductor, cleaning has conventionally been performed. For example, a technique disclosed in Japanese Patent Laying-Open No. 6-314679 (Patent Document 1) and known RCA cleaning are exemplified as such a cleaning method.

The method of cleaning a semiconductor substrate disclosed in Patent Document 1 is performed in the following manner. Namely, a silicon (Si) substrate is cleaned with ultrapure water containing ozone to thereby form an Si oxide film, so that particles and a metal impurity are taken into the inside or into a surface of this Si oxide film. Then, this Si substrate is cleaned with a diluted hydrofluoric acid aqueous solution so that the Si oxide film is etched away and simultaneously the particles and the metal impurity are removed.

### SUMMARY OF THE INVENTION

SiC has a wide band gap, and it is greater in dielectric breakdown electric field and thermal conductivity than Si. Meanwhile, it is as high as Si in carrier mobility and it is also high in saturated drift velocity of electrons. Therefore, SiC is expected to be applied to a semiconductor device required to achieve higher efficiency, a higher reverse breakdown voltage and a greater capacity. Then, the present inventor noted use of an SiC semiconductor for a semiconductor device. In using an SiC semiconductor for a semiconductor device, a surface of the SiC semiconductor should be cleaned.

The present inventor revealed for the first time that application of the cleaning method in Patent Document 1 above to an SiC semiconductor is less likely to oxidize a surface of the SiC semiconductor because SiC is a compound more thermally stable than Si. Namely, though the cleaning method in Patent Document 1 above can oxidize a surface of an Si semiconductor, it cannot sufficiently oxidize a surface of an SiC semiconductor. Therefore, the surface of the SiC semiconductor cannot sufficiently be cleaned. If an epitaxially grown layer or a semiconductor device is manufactured with an SiC semiconductor which has not sufficiently been cleaned, characteristics of the epitaxially grown layer or the semiconductor device become poor.

Therefore, one object of the present invention is to provide a method of cleaning an SiC semiconductor capable of exhibiting an effect of cleaning an SiC semiconductor by adding a dry process to a process for cleaning an SiC semiconductor that has been performed in a wet process so far.

Another object of the present invention is to provide an SiC semiconductor and an SiC semiconductor device capable of achieving improved characteristics.

A method of cleaning an SiC semiconductor according to the present invention includes the steps of forming an oxide film on a surface of an SiC semiconductor and removing the oxide film. In the forming step, the oxide film is formed in a dry atmosphere at a temperature not lower than 700° C. that contains oxygen (O) atoms.

As a result of dedicated studies of conditions for exhibiting an effect of cleaning an SiC semiconductor, the present inventor found that a surface of the SiC semiconductor, which is a stable compound, can effectively be oxidized in a dry atmosphere at a temperature not lower than 700° C. that contains O. Therefore, according to the method of cleaning an SiC semiconductor in the present invention, the surface of the SiC semiconductor can effectively be oxidized and hence an oxide film can be formed with an impurity, particles or the like deposited onto the surface being taken therein. By removing this oxide film, the impurity, particles or the like at the surface of the SiC semiconductor can be removed. Therefore, the method of cleaning an SiC semiconductor according to the present invention can exhibit an effect of cleaning an SiC semiconductor.

In the method of cleaning an SiC semiconductor above, preferably, the dry atmosphere has oxygen concentration not lower than 1% and not higher than 100%.

If oxygen concentration is lower than 1%, oxidation reaction of SiC cannot sufficiently be achieved. Alternatively, by increasing oxygen concentration, oxidation reaction of SiC can sufficiently be promoted.

In the method of cleaning an SiC semiconductor above, preferably, the dry atmosphere contains water vapor. Use of water vapor as an oxygen atom source can also allow formation of an oxide film on the surface of the SiC semiconductor.

In the method of cleaning an SiC semiconductor above, preferably, in the removing step, the oxide film is removed with hydrogen fluoride (HF).

Since the oxide film can thus readily be removed, the oxide film remaining on the surface can be decreased.

In the method of cleaning an SiC semiconductor above, preferably, in the forming step, the oxide film having a thickness not smaller than one molecular layer and not greater than 30 nm is formed.

By forming an oxide film having a thickness not smaller than one molecular layer, an impurity, particles or the like at the surface can be taken into the oxide film. By forming an oxide film not greater than 30 nm and preferably not greater than 10 nm, a region in the SiC semiconductor to be removed can be decreased.

An SiC semiconductor according to the present invention is an SiC semiconductor having a surface, and the surface has metal surface density not higher than 1×10¹² cm⁻².

According to the SiC semiconductor in the present invention, metal surface density at the surface can be lowered to the range above. Therefore, in forming an epitaxial layer on this surface, characteristics of the epitaxial layer can be improved. Alternatively, in forming an oxide film constituting a semiconductor device on this surface, a metal impurity present at an interface between the SiC semiconductor and the oxide film can be decreased and the metal impurity present in the oxide film can also be decreased. Therefore, in a case where this oxide film constitutes an SiC semiconductor device, characteristics of the SiC semiconductor device can be improved.

An SiC semiconductor device according to the present invention includes the SiC semiconductor above and an oxide film formed on the surface of the SiC semiconductor above.

According to the SiC semiconductor device in the present invention, a metal impurity present at an interface between the SiC semiconductor and the oxide film can be decreased and the metal impurity present in the oxide film can also be decreased. Thus, a reverse breakdown voltage of the oxide film can be improved. Therefore, characteristics of the SiC semiconductor device can be improved.

As described above, according to the method of cleaning an SiC semiconductor in the present invention, an effect of cleaning the SiC semiconductor can be exhibited by forming an oxide film in a dry atmosphere at a temperature not lower than 700° C. that contains O atoms.

In addition, according to the SiC semiconductor and the SiC semiconductor device in the present invention, since metal surface density at the surface of the SiC semiconductor is not higher than 1×10¹² cm⁻², the SiC semiconductor and the SiC semiconductor device capable of achieving improved characteristics can be realized.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross-sectional view schematically showing an SiC substrate representing an SiC semiconductor in a first embodiment of the present invention.

FIG. 2 is a flowchart showing a method of cleaning an SiC substrate representing an SiC semiconductor in the first embodiment of the present invention.

FIGS. 3 and 4 are cross-sectional views each schematically showing one step in the method of cleaning an SiC substrate representing an SiC semiconductor in the first embodiment of the present invention.

FIG. 5 is a cross-sectional view schematically showing an epitaxial wafer representing an SiC semiconductor in a second embodiment of the present invention.

FIG. 6 is a flowchart showing a method of cleaning an epitaxial wafer representing an SiC semiconductor in the second embodiment of the present invention.

FIGS. 7 to 9 are cross-sectional views each schematically showing one step in the method of cleaning an epitaxial wafer representing an SiC semiconductor in the second embodiment of the present invention.

FIG. 10 is a cross-sectional view schematically showing a MOSFET representing an SiC semiconductor device in a third embodiment of the present invention.

FIG. 11 is a flowchart showing a method of manufacturing a MOSFET representing an SiC semiconductor device in the third embodiment of the present invention.

FIGS. 12 and 13 are cross-sectional views each schematically showing one step in the method of manufacturing a MOSFET representing an SiC semiconductor device in the third embodiment of the present invention.

FIG. 14 is a cross-sectional view schematically showing an epitaxial wafer cleaned in an Example.

### DESCRIPTION OF THE PREFERRED EMBODIMENTS

An embodiment of the present invention will be described hereinafter with reference to the drawings. In the drawings below, the same or corresponding elements have the same reference characters allotted and description thereof will not be repeated.

### First Embodiment

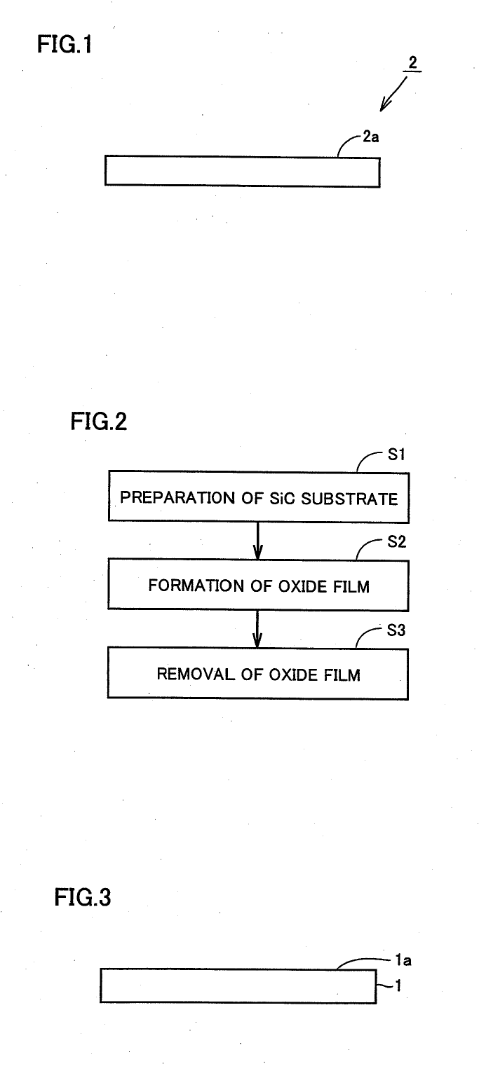

FIG. 1 is a cross-sectional view schematically showing an SiC substrate 2 representing an SiC semiconductor in a first embodiment of the present invention. SiC substrate 2 representing one embodiment of the SiC semiconductor according to the present invention will be described with reference to FIG. 1.

As shown in FIG. 1, SiC substrate 2 has a surface 2a. Surface 2a has metal surface density not higher than 1×10¹² cm⁻² and preferably not higher than 1×10¹⁰ cm⁻². Though lower metal surface density is preferred, from a point of view of ease in manufacturing, for example, the lower limit value is 1×10⁷ cm⁻².

Here, metal surface density refers to a value obtained by measuring concentration of various metals such as titanium (Ti), iron (Fe), nickel (Ni), and copper (Cu) with total X-ray reflection fluorescence (TXRF). Namely, metal surface density refers to surface density of a measurable metal impurity that is present at surface 2a.

SiC substrate 2 has a conductive type, for example, of n, and has resistance, for example, of 0.02 Ωcm. Though a polytype of SiC substrate 2 is not particularly limited, it is preferably 4H—SiC.

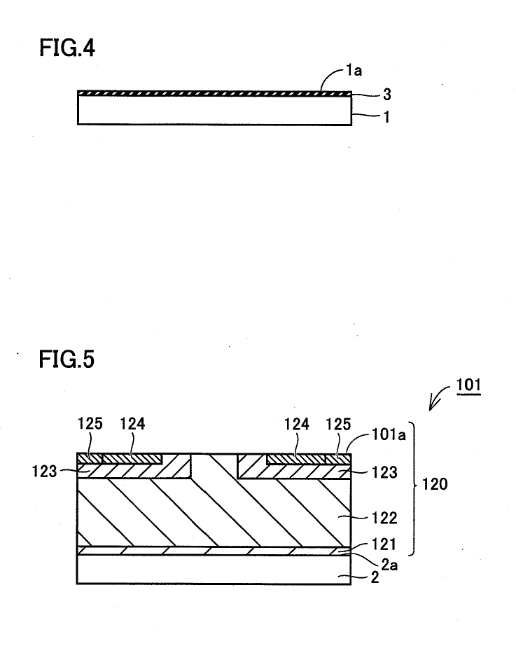

FIG. 2 is a flowchart showing a method of cleaning SiC substrate 2 representing an SiC semiconductor in the first embodiment of the present invention. FIGS. 3 and 4 are cross-sectional views each schematically showing one step in the method of cleaning an SiC substrate representing an SiC semiconductor in the first embodiment of the present invention. The method of cleaning an SiC substrate representing an SiC semiconductor in one embodiment of the present invention will be described with reference to FIGS. 1 to 4. In the present embodiment, a method of cleaning an SiC substrate 1 shown in FIG. 3 as an SiC semiconductor will be described.

As shown in FIGS. 2 and 3, initially, SiC substrate 1 having a surface 1a is prepared (step S1). Though SiC substrate 1 is not particularly limited, for example, it can be prepared with the following method.

Specifically, an SiC ingot grown, for example, with a vapor phase deposition method such as a sublimation method, a CVD (Chemical Vapor Deposition) method, an HVPE (Hydride Vapor Phase Epitaxy) method, an MBE (Molecular Beam Epitaxy) method, and an OMVPE (OrganoMetallic Vapor Phase Epitaxy) method, a liquid phase deposition method such as a flux method and a high nitrogen pressure solution method, and the like is prepared. Thereafter, an SiC substrate having a surface is cut from the SiC ingot. A cutting method is not particularly limited, and an SiC substrate is cut from the SiC ingot by slicing or the like. A plane orientation of the SiC substrate is not particularly limited.

Then, the surface of the cut SiC substrate is polished. A surface alone may be polished, and a back surface opposite to the surface may further be polished. Though a polishing method is not particularly limited, in order to planarize the surface and to lessen damage such as flaws, for example, CMP (Chemical Mechanical Polishing) is performed. In CMP, colloidal silica is employed as an abrasive, diamond or chromium oxide is employed as an abrasive grain, and an adhesive, a wax or the like is employed as a fixing agent. Together with or instead of CMP, other polishing such as an electropolishing method, a chemical polishing method, a mechanical polishing method, or the like may further be performed. Alternatively, polishing may not be performed. Thus, SiC substrate 1 having surface 1a shown in FIG. 3 can be prepared. For example, a substrate having an n conductive type and resistance of 0.02 Ωcm is employed as such SiC substrate 1.

Then, surface 1a of SiC substrate 1 is cleaned with an acid. In acid cleaning, for example, at least one acid solution of SPM containing sulfuric acid (H₂SO₄) and a hydrogen peroxide solution (H₂O₂), hydrochloric acid (HCl), and HCl and nitric acid (HNO₃) is employed for cleaning surface 1a of SiC substrate 1. An organic substance at surface 1a of SiC substrate 1 can be removed by acid cleaning. Instead of or together with acid cleaning, RCA cleaning may be performed. Acid cleaning and RCA cleaning may not be performed.

Then, surface 1a of SiC substrate 1 is subjected to HF cleaning. In HF cleaning, surface 1a of SiC substrate 1 is cleaned with HF. As a result of HF cleaning, a natural oxide film formed on surface 1a of SiC substrate 1 can be removed. HF cleaning may not be performed.

Then, as shown in FIGS. 2 and 4, an oxide film 3 is formed on surface 1a of SiC substrate 1 in a dry atmosphere at a temperature not lower than 700° C. that contains O atoms (step S2). The dry atmosphere means formation of oxide film 3 in a vapor phase and it may contain an unintended liquid phase component. Namely, by subjecting surface 1a of SiC substrate 1 to heat treatment in a vapor phase at a temperature not lower than 700° C. that contains a gas having O atoms, surface 1a is oxidized to thereby form oxide film 3.

In this step S2, the dry atmosphere containing O atoms is an atmosphere formed of an oxidizing gas containing a gas having O atoms. The dry atmosphere containing O atoms is composed, for example, of an oxygen gas (O₂), a gas mixture of an O₂ gas and a nitrogen (N₂) gas, a gas mixture of an O₂ gas and an inert gas such as argon (Ar), a gas containing nitrogen oxide (NOₓ) such as a nitric oxide (NO) gas or a nitrous oxide (N₂O) gas, a gas containing water vapor, or the like. In addition, a gas high in purity is preferably employed, and it is preferred not to use atmosphere because atmosphere (air) contains an impurity.

Oxygen concentration in the dry atmosphere is preferably not lower than 1% and not higher than 100%. If oxygen concentration is lower than 1%, oxidation reaction of SiC cannot sufficiently be achieved. Alternatively, by increasing oxygen concentration, oxidation reaction of SiC can sufficiently be promoted. It is noted that the oxygen concentration above is expressed in volume %.

In this step S2, oxide film 3 is formed on surface 1a of SiC substrate 1 at a temperature not lower than 700° C. and preferably not higher than 1200° C. If the temperature is not lower than 700° C., oxidation reaction to the surface of SiC, which is a stable compound, can be promoted. If the temperature is not higher than 1200° C., controllability of oxidation reaction can be enhanced.

Though a method of subjecting SiC substrate 1 to heat treatment (thermal oxidation) at a temperature not lower than 700° C. in step S2 is not particularly limited, for example, a technique using a heat treatment apparatus such as a known oxidation furnace, an RTA (Rapid Thermal Annealing) furnace, or a furnace in which transfer to a high-temperature furnace is carried out by means of a belt conveyor and oxidation is achieved in a short period of time can be adopted. Since a temperature can be raised and lowered rapidly, an RTA furnace is more preferably employed in step S2.

In addition, in this step S2, oxide film 3 having a thickness, for example, not smaller than one molecular layer and not greater than 30 nm is formed and oxide film 3 not greater than 10 nm is preferred. Namely, oxide film 3 not smaller than one molecular layer and not greater than 30 nm and further preferably not greater than 10 nm is preferably formed toward the back surface from surface 1a. By forming oxide film 3 having a thickness not smaller than one molecular layer, an impurity, particles or the like at surface 1a can be taken into oxide film 3. By forming oxide film 3 not greater than 30 nm, oxide film 3 can readily be removed in step S3 of removing oxide film 3 which will be described later.

By oxidizing surface 1a of SiC substrate 1 in this step S2, particles, a metal impurity or the like deposited onto surface 1a of SiC substrate 1 can be taken into the surface or into the inside of oxide film 3. It is noted that the oxide film is composed, for example, of silicon oxide.

Then, as shown in FIGS. 1 and 2, oxide film 3 is removed (step S3). In this step S3, since oxide film 3 into which an impurity, particles or the like has (have) been taken is removed, the impurity, particles or the like at surface 1a of SiC substrate 1 prepared in step S1 can be removed.

In this step S3, for example, HF or preferably at least 0.1% and at most 10% diluted HF (DHF) is used for removal. In removal with the use of HF, for example, oxide film 3 can be removed by holding HF in a reaction vessel and immersing SiC substrate 1 in HF.

A method of removing oxide film 3 is not limited to HF. For example, the oxide film may be removed with other solutions such as NH₄F (ammonium fluoride), and oxide film 3 may be removed with dry etching in a vapor phase such as plasma.

Alternatively, in wet cleaning using such a liquid phase as HF, surface 1a of SiC substrate 1 may be cleaned with pure water after wet cleaning (a pure water rinsing step). Pure water is preferably ultrapure water. Cleaning may be carried out, with ultrasound being applied to pure water. It is noted that this pure water rinsing step may not be performed.

In addition, in wet cleaning, the surface of the SiC substrate may be dried (a drying step). A drying method is not particularly limited, and for example, a spin dryer or the like is used for drying. It is noted that this drying step may not be performed.

By performing the steps (steps S1 to S3) above, an impurity, particles (a contaminant) or the like deposited onto surface 1a of SiC substrate 1 is (are) removed, so that SiC substrate 2 having surface 2a low in metal surface density shown in FIG. 1 can be manufactured. It is noted that steps S2 and S3 above may be repeated.

In succession, an effect of the method of cleaning SiC substrate 1 representing an SiC semiconductor in the present embodiment will be described in comparison with the conventional technique.

Even though the method of cleaning an Si substrate representing the conventional technique is applied to an SiC substrate, an oxide film is less likely to be formed on the SiC substrate because the SiC substrate has such a property that it is less likely to be oxidized than the Si substrate. For example, when the cleaning method in Patent Document 1 above is applied to the SiC substrate, ozone is decomposed and hence contribution to oxidation of the surface of the SiC substrate is hardly likely. For example, when RCA cleaning is applied to the SiC substrate, oxidation reaction to SiC does not proceed with the use of an agent containing sulfuric acid and hydrogen peroxide, and contribution to oxidation of the surface of the SiC substrate is hardly likely. Thus, application of the conventional method of cleaning an Si substrate results in a significantly low effect of cleaning the SiC substrate. Therefore, even when the SiC substrate is cleaned with the conventional method of cleaning an Si substrate, cleaning of the surface of the SiC substrate has been insufficient. Thus, there has been no technique established as the method of cleaning an SiC substrate.

Then, as a result of the present inventor's dedicated studies of a method of oxidizing a surface of an SiC substrate in order to exhibit an effect of cleaning an SiC semiconductor, the present inventor noted the fact that the SiC substrate is chemically stable and SiC crystal is sufficient in strength. The present inventor found that damage or diffusion of a contaminant in an SiC substrate is less likely even with an oxidizing method which may cause damage in an Si substrate and diffusion of a contaminant present at the surface into the Si substrate, and completed the method of cleaning an SiC substrate in the present embodiment described above. Namely, the method of cleaning SiC substrate 1 representing an SiC semiconductor in the present embodiment includes step S2 of forming oxide film 3 on surface 1a of SiC substrate 1 and step S3 of removing oxide film 3, and in step S2 of forming, oxide film 3 is formed in a dry atmosphere at a temperature not lower than 700° C. that contains O atoms.

By forming oxide film 3 in a dry atmosphere at a temperature not lower than 700° C. that contains O atoms in step S2, surface 1a of SiC substrate 1, which is a stable compound, can effectively be oxidized. In particular, since oxide film 3 is formed in a dry atmosphere, influence by a plane orientation can be lessened as compared with a case where oxide film 3 is formed with the use of a liquid phase. Therefore, a metal impurity such as Ti, particles or the like deposited onto surface 1a of SiC substrate 1 can evenly be taken into oxide film 3. By removing oxide film 3 in step S3, the impurity, particles or the like taken into the inside or into the surface of oxide film 3 can be removed.

Application of heat treatment in a dry atmosphere not lower than 700° C. to an Si substrate may cause roughening of the surface of the Si substrate and diffusion of a contaminant present at the surface into the Si substrate. On the other hand, SiC substrate 1 is chemically stable. Therefore, even though heat treatment in a dry atmosphere not lower than 700° C. is applied, roughening of the surface and diffusion of a contaminant can be lessened as compared with the Si substrate.

Therefore, the method of cleaning SiC substrate 1 in the present embodiment can exhibit an effect of cleaning surface 1a.

By thus cleaning SiC substrate 1, as shown in FIG. 1, SiC substrate 2 having surface 2a of which metal surface density is not higher than 1×10¹² cm⁻² can be realized. As an epitaxial layer is formed on surface 2a of such SiC substrate 2, characteristics of the epitaxial layer can be improved.

### Second Embodiment

FIG. 5 is a cross-sectional view schematically showing an epitaxial wafer 101 representing an SiC semiconductor in a second embodiment of the present invention. Epitaxial wafer 101 representing one embodiment of the present invention will be described with reference to FIG. 5.

As shown in FIG. 5, epitaxial wafer 101 includes SiC substrate 2 and an epitaxial layer 120. Epitaxial layer 120 includes a buffer layer 121, a reverse breakdown voltage holding layer 122, a well region 123, a source region 124, and a contact region 125.

A surface 101a of epitaxial wafer 101 (in the present embodiment, surface 101a of epitaxial layer 120) has metal surface density not higher than 1×10¹² cm⁻² and preferably not higher than 1×10¹⁰ cm⁻². The lower limit value is, for example, 1×10⁷ cm⁻².

SiC substrate 2 has surface 2a cleaned with the cleaning method described in the first embodiment. It is noted that SiC substrate 1 shown in FIG. 3 on which steps S2 and S3 have not been performed may be employed instead of SiC substrate 2.

Buffer layer 121 is formed on surface 2a of SiC substrate 2. Buffer layer 121 has an n conductive type and a thickness, for example, of 0.5 μm. In addition, concentration of an n-type conductive impurity in buffer layer 121 is, for example, 5×10¹⁷ cm⁻³.

Reverse breakdown voltage holding layer 122 is formed on buffer layer 121 and it is composed of SiC having an n conductive type. For example, reverse breakdown voltage holding layer 122 has a thickness of 10 μm and concentration of the n-type conductive impurity, for example, of 5×10¹⁵ cm⁻³.

A plurality of well regions 123 having a p conductive type are formed in the surface of this reverse breakdown voltage holding layer 122, at a distance from each other. In well region 123, source region 124 having an n⁺ conductive type is formed in a surface layer of well region 123. In addition, contact region 125 having a p⁺ conductive type is formed at a position adjacent to this source region 124.

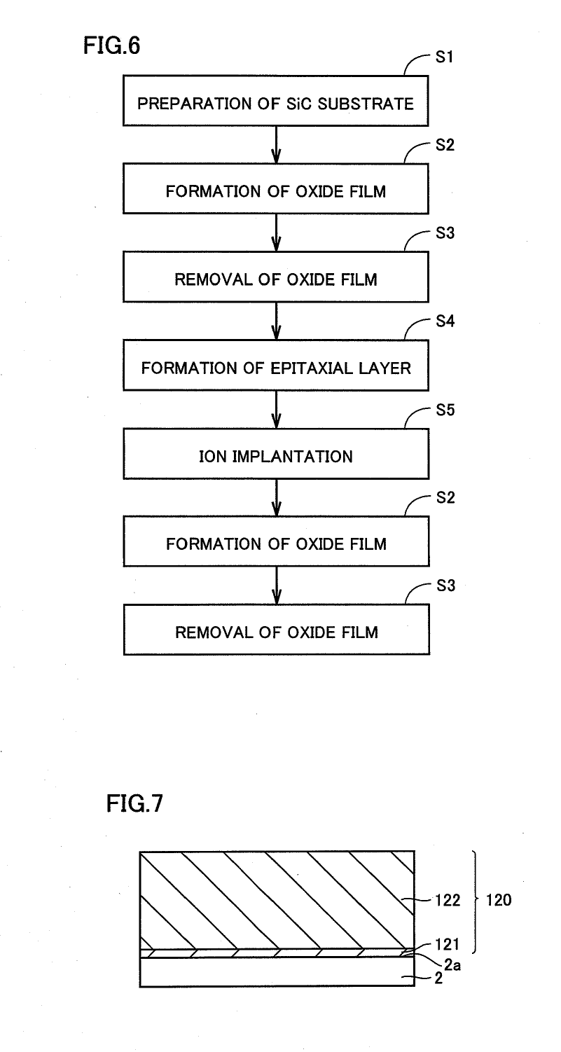

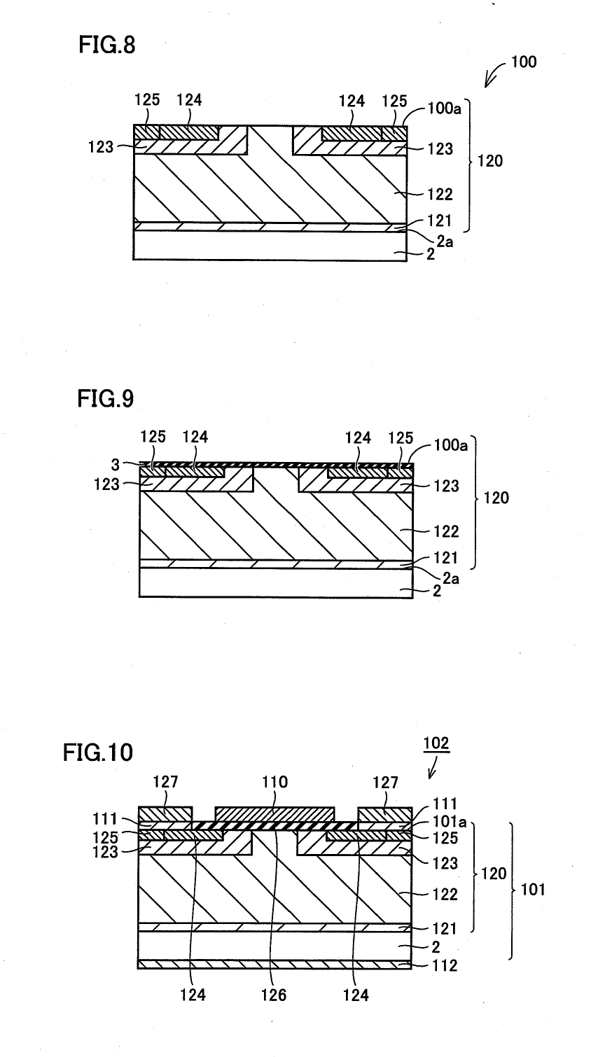

FIG. 6 is a flowchart showing a method of cleaning an epitaxial wafer representing an SiC semiconductor in the second embodiment of the present invention. FIGS. 7 to 9 are cross-sectional views each schematically showing one step in the method of cleaning an epitaxial wafer representing an SiC semiconductor in the second embodiment of the present invention. The method of cleaning an epitaxial wafer representing an SiC semiconductor in the present embodiment will be described with reference to FIGS. 1 to 9. In the present embodiment, a method of cleaning an epitaxial wafer 100 shown in FIG. 8 and representing an SiC semiconductor will be described.

Initially, as shown in FIGS. 3 and 6, SiC substrate 1 is prepared (step S1). Since step S1 is the same as in the first embodiment, description thereof will not be repeated.

Then, as shown in FIGS. 4 and 6, an oxide film is formed on surface 1a of SiC substrate 1 (step S2) and thereafter oxide film 3 is removed (step S3). Since steps S2 and S3 are the same as in the first embodiment, description thereof will not be repeated. Surface 1a of SiC substrate 1 can thus be cleaned and SiC substrate 2 having surface 2a low in metal surface density shown in FIG. 1 can be prepared. It is noted that cleaning of surface 2a of SiC substrate 2 (that is, steps S2 and S3) may not be performed.

Then, as shown in FIGS. 6 and 7, epitaxial layer 120 is formed on surface 2a of SiC substrate 2 with a vapor phase deposition method, a liquid phase deposition method, or the like (step S4). In the present embodiment, for example, epitaxial layer 120 is formed as follows.

Specifically, as shown in FIG. 7, buffer layer 121 is formed on surface 2a of SiC substrate 2. Buffer layer 121 is an epitaxial layer composed, for example, of SiC having an n conductive type and a thickness, for example, of 0.5 μm. In addition, concentration of a conductive impurity in buffer layer 121 is, for example, 5×10¹⁷ cm⁻³.

Thereafter, as shown in FIG. 7, reverse breakdown voltage holding layer 122 is formed on buffer layer 121. A layer composed of SiC having an n conductive type is formed as reverse breakdown voltage holding layer 122 with a vapor phase deposition method, a liquid phase deposition method, or the like. Reverse breakdown voltage holding layer 122 has a thickness, for example, of 15 μm. Concentration of an n-type conductive impurity in reverse breakdown voltage holding layer 122 is, for example, 5×10¹⁵ cm⁻³.

Then, as shown in FIGS. 6 and 8, ions are implanted into epitaxial layer 120 (step S5). In the present embodiment, as shown in FIG. 8, p-type well region 123, n⁺ source region 124, and p⁺ contact region 125 are formed as follows. Initially, an impurity having a p conductive type is selectively implanted into a part of reverse breakdown voltage holding layer 122, to thereby form well region 123. Thereafter, an n-type conductive impurity is selectively implanted into a prescribed region, to thereby form source region 124. In addition, a p-type conductive impurity is selectively implanted into a prescribed region, to thereby form contact region 125. It is noted that selective implantation of an impurity is carried out, for example, by using a mask formed of an oxide film.

In ion implantation step S5 above, each implantation profile takes into account a thickness to be oxidized in step S2 (thickness of oxide film 3 in FIG. 9) which will be described later.

After such ion implantation step S5, activation annealing treatment may be performed. For example, annealing for 30 minutes at a heating temperature of 1700° C. in an argon atmosphere is performed.

Through these steps, as shown in FIG. 8, epitaxial wafer 100 including SiC substrate 2 and epitaxial layer 120 formed on SiC substrate 2 and having an ion-implanted surface 100a can be prepared.

Then, surface 100a of epitaxial wafer 100 is cleaned. Specifically, as shown in FIGS. 6 and 9, oxide film 3 is formed on surface 100a of epitaxial wafer 100 in a dry atmosphere at a temperature not lower than 700° C. that contains O atoms (step S2). Since this step S2 is the same as step S2 of forming an oxide film on surface 1a of SiC substrate 1 in the first embodiment, description thereof will not be repeated.

If damage such as surface roughening is caused in surface 100a by ion implantation into epitaxial wafer 100 in step S5, the damaged layer may be oxidized for the purpose of removing this damaged layer. In this case, for example, oxidation to a depth exceeding 30 nm and not greater than 100 nm from surface 100a toward SiC substrate 2 is carried out. Namely, oxide film 3 having a thickness exceeding 30 nm and not greater than 100 nm is formed on surface 100a of epitaxial wafer 100.

Alternatively, in aiming to clean only surface 100a without removing the damaged layer, an oxidized region in the ion-implanted layer (well region 123, source region 124, and contact region 125) formed in surface 100a (a region in epitaxial wafer 100 to be removed in step S3 which will be described later) can be made smaller, and hence oxide film 3 is formed to have a thickness preferably not smaller than one molecular layer and not greater than 30 nm and further preferably not greater than 10 nm.

Then, oxide film 3 formed on surface 100a of epitaxial wafer 100 is removed (step S3). Since this step S3 is the same as step S3 of removing oxide film 3 formed on surface 1a of SiC substrate 1 in the first embodiment, description thereof will not be repeated.

By performing the steps (S1 to S5) above, an impurity, particles or the like deposited onto surface 100a of epitaxial wafer 100 can be cleaned. It is noted that step S2 and step S3 may be repeated and other cleaning steps such as acid cleaning, RCA cleaning and HF cleaning may further be included, as in the first embodiment. Thus, as shown in FIG. 5, epitaxial wafer 101 having surface 101a low in metal surface density can be realized.

As described above, according to the method of cleaning epitaxial wafer 100 representing an SiC semiconductor in the present embodiment, oxide film 3 can be formed in a dry atmosphere at a temperature not lower than 700° C. that contains O atoms, which cannot be adopted due to occurrence of surface roughening, diffusion of a contaminant or the like in Si. This is because SiC is chemically stable. Thus, surface 100a of SiC epitaxial wafer 100 which is less likely to be oxidized can effectively be oxidized. Therefore, an effect of cleaning surface 100a of epitaxial wafer 100 can be exhibited by removing this oxide film 3.

According to the method of cleaning epitaxial wafer 100 representing an SiC semiconductor in the present embodiment, as shown in FIG. 5, epitaxial wafer 101 having surface 101a with less contaminant and metal surface density not higher than 1×10¹² cm⁻² can be manufactured. When a semiconductor device is fabricated by forming an insulating film constituting the semiconductor device, such as a gate oxide film, on this surface 101a, characteristics of the insulating film can be improved and an impurity, particles or the like present at an interface between surface 101a and the insulating film and in the insulating film can be decreased. Therefore, a reverse breakdown voltage of the semiconductor device at the time of application of a reverse voltage can be improved and stability and long-time reliability of an operation at the time of application of a forward voltage can be improved. Thus, the method of cleaning an SiC semiconductor according to the present invention is particularly suitably used for surface 100a of epitaxial wafer 100 before formation of a gate oxide film.

Since epitaxial wafer 101 cleaned in the present embodiment can achieve improved characteristics of an insulating film by forming the insulating film on cleaned surface 101a, it can suitably be employed for a semiconductor device having an insulating film. Therefore, epitaxial wafer 101 cleaned in the present embodiment can suitably be employed, for example, for a semiconductor device having an insulating gate type field effect portion such as a MOSFET (Metal Oxide Semiconductor Field Effect Transistor) or an IGBT (Insulated Gate Bipolar Transistor), a WET (Junction Field-Effect Transistor), and the like.

Here, in the first embodiment, the method of cleaning surface 1a of SiC substrate 1 has been described. In the second embodiment, the method of cleaning surface 100a of epitaxial wafer 100 including SiC substrate 2 and SiC epitaxial layer 120 formed on SiC substrate 2, SiC epitaxial layer 120 having ion-implanted surface 100a, has been described. The cleaning method according to the present invention, however, is also applicable to an SiC epitaxial layer having a surface not implanted with ions. In addition, in cleaning epitaxial wafer 100, at least one of a surface of an SiC substrate implementing epitaxial wafer 100 and surface 100a of epitaxial wafer 100 may be cleaned. Further, in cleaning an epitaxial wafer, a surface of an epitaxial wafer not including SiC substrate 2 may be cleaned, or a surface of an epitaxial wafer including a hetero substrate other than the SiC substrate may be cleaned.

Namely, the method of cleaning an SiC semiconductor according to the present invention includes (i) a case of cleaning an SiC substrate, (ii) a case of cleaning at least one of a surface of an epitaxial layer and an SiC substrate in an epitaxial wafer having the SiC substrate and an SiC epitaxial layer formed on the SiC substrate, (iii) a case of cleaning a surface of an epitaxial wafer having an SiC epitaxial layer not including an SiC substrate, and (iv) a case of cleaning a surface of an epitaxial wafer having a hetero substrate and an SiC epitaxial layer formed on the hetero substrate, and the SiC epitaxial layer in (ii) to (iv) includes a layer in which ions have been implanted through a surface and a layer not implanted with ions.

Further, as an SiC semiconductor having a surface of which metal surface density is not higher than 1×10¹² cm⁻², SiC substrate 2 has been described in the first embodiment and epitaxial wafer 101 including SiC substrate 2 and SiC epitaxial layer 120 formed on SiC substrate 2, SiC epitaxial layer 120 having ion-implanted surface 101a, has been described in the second embodiment. The SiC semiconductor according to the present invention, however, may be an epitaxial wafer not including SiC substrate 2 or an epitaxial wafer including a hetero substrate other than the SiC substrate.

Namely, the SiC semiconductor according to the present invention includes (i) an SiC substrate, (ii) an epitaxial wafer having an SiC substrate and an SiC epitaxial layer formed on the SiC substrate, (iii) an epitaxial wafer having an SiC epitaxial layer not including an SiC substrate, and (iv) an epitaxial wafer having a hetero substrate and an SiC epitaxial layer formed on the hetero substrate, and the SiC epitaxial layer in (ii) to (iv) includes a layer in which ions have been implanted through a surface and a layer not implanted with ions.

### Third Embodiment

FIG. 10 is a cross-sectional view schematically showing a MOSFET 102 representing an SiC semiconductor device in a third embodiment of the present invention. MOSFET 102 representing one embodiment of an SiC semiconductor device according to the present invention will be described with reference to FIG. 10.

As shown in FIG. 10, MOSFET 102 is a vertical DiMOSFET (Double Implanted Metal Oxide Semiconductor Field Effect Transistor) and it includes epitaxial wafer 101 in the second embodiment, an oxide film 126, a source electrode 111, an upper source electrode 127, a gate electrode 110, and a drain electrode 112. Epitaxial wafer 101 includes SiC substrate 2 and epitaxial layer 120. Epitaxial layer 120 has buffer layer 121, reverse breakdown voltage holding layer 122, well region 123, source region 124, and contact region 125.

Metal surface density of surface 101a of epitaxial layer 120 is not higher than 1×10¹² cm⁻². Oxide film 126 which is a gate insulating film is provided on this surface 101a in contact therewith. Specifically, oxide film 126 is formed to extend from above source region 124 in one well region 123 over one well region 123, reverse breakdown voltage holding layer 122 exposed between two well regions 123 and the other well region 123 as far as above source region 124 in the other well region 123.

Gate electrode 110 is formed on oxide film 126. In addition, source electrode 111 is formed on source region 124 and contact region 125. Upper source electrode 127 is formed on this source electrode 111. Drain electrode 112 is formed on a back surface opposite to surface 2a of SiC substrate 2.

A maximum value of nitrogen atom concentration in a region within 10 nm from an interface between oxide film 126 and source region 124, contact region 125, well region 123, and reverse breakdown voltage holding layer 122 in epitaxial layer 120 is not lower than 1×10²¹ cm⁻³. Thus, mobility in particular in a channel region under oxide film 126 (a portion of well region 123 between source region 124 and reverse breakdown voltage holding layer 122, which is in contact with oxide film 126) can be improved.

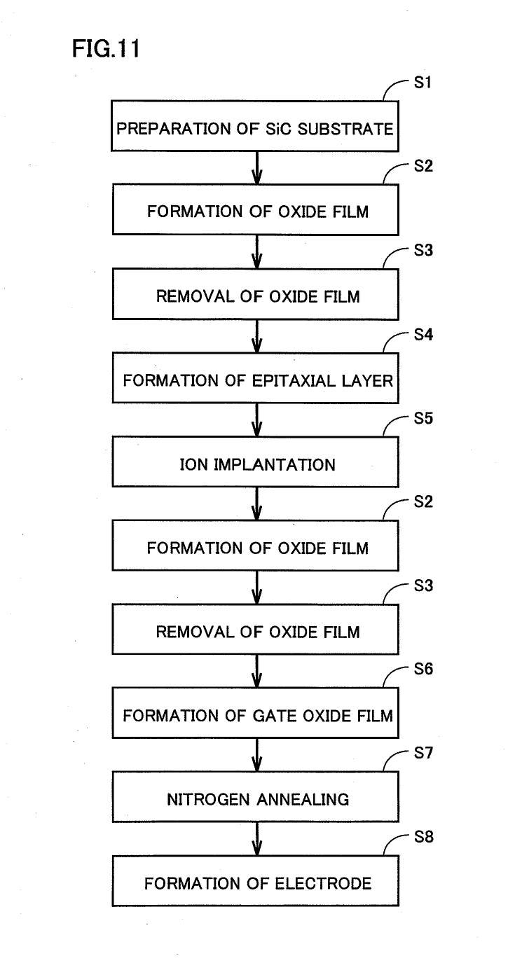

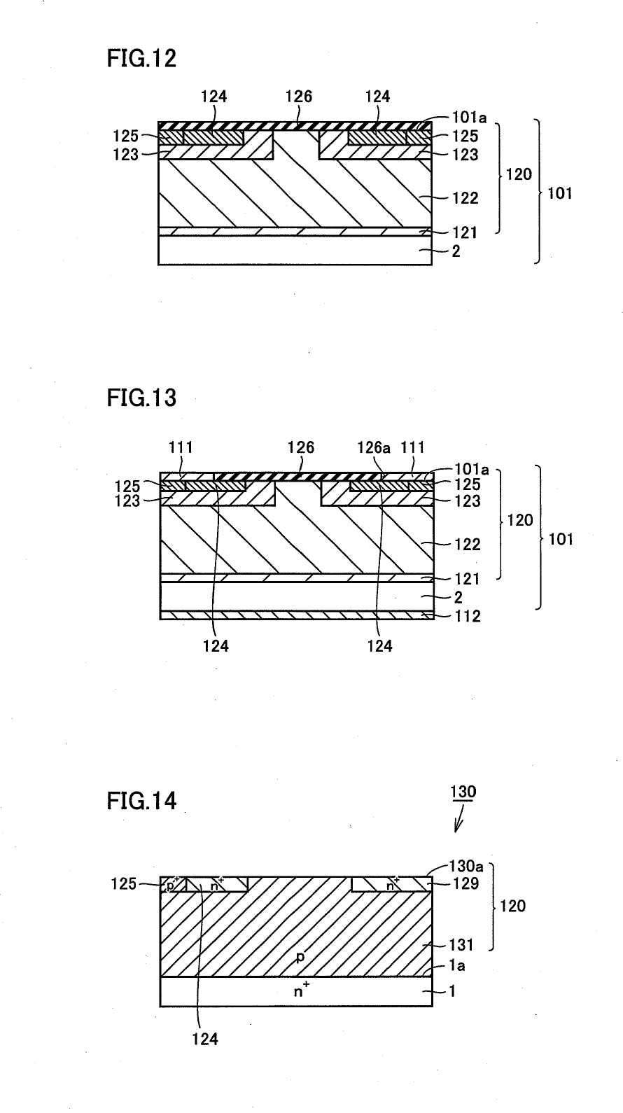

FIG. 11 is a flowchart showing a method of manufacturing MOSFET 102 representing an SiC semiconductor device in the third embodiment of the present invention. FIGS. 12 and 13 are cross-sectional views each schematically showing one step in the method of manufacturing a MOSFET representing an SiC semiconductor device in the third embodiment of the present invention. A method of manufacturing MOSFET 102 in the present embodiment will be described with reference to FIGS. 5 and 10 to 13.

Initially, as shown in FIGS. 5 and 11, epitaxial wafer 101 shown in FIG. 5 is manufactured in accordance with the method of cleaning an epitaxial layer in the second embodiment (steps S1 to S5). Since steps S1 to S5 are the same as in the second embodiment, description thereof will not be repeated.

Then, as shown in FIGS. 11 and 12, oxide film 126 is formed on surface 101a of epitaxial wafer 101 (step S6). Specifically, as shown in FIG. 12, oxide film 126 is formed to cover reverse breakdown voltage holding layer 122, well region 123, source region 124, and contact region 125. This formation can be achieved, for example, by thermal oxidation (dry oxidation). In thermal oxidation, for example, heating to a high temperature in an atmosphere containing oxygen atoms such as O₂, O₃ and N₂O is carried out. For example, conditions for thermal oxidation are such that a heating temperature is set to 1200° C. and a heating time period is set to 30 minutes. It is noted that formation of oxide film 126 is not limited to formation by thermal oxidation, and for example, it may be formed, for example, with a CVD method, a sputtering method or the like. Oxide film 126 is implemented, for example, by a silicon oxide film having a thickness of 50 nm.

Thereafter, nitrogen annealing is performed (step S7). Specifically, annealing treatment in a nitric oxide (NO) atmosphere is performed. For example, conditions in this treatment are such that a heating temperature is set to 1100° C. and a heating time period is set to 120 minutes. Consequently, nitrogen atoms can be introduced in the vicinity of the interface between each of reverse breakdown voltage holding layer 122, well region 123, source region 124, and contact region 125 and oxide film 126.

After this nitrogen annealing step (step S7), annealing treatment using an argon gas which is an inert gas may further be performed. For example, conditions in this treatment are such that a heating temperature is set to 1100° C. and a heating time period is set to 60 minutes.

After this nitrogen annealing step (step S7) and the annealing treatment using the argon gas, surface cleaning such as organic solvent cleaning, acid cleaning, RCA cleaning, or the like may further be performed.

Then, as shown in FIGS. 10, 11 and 13, an electrode is formed (step S8). Initially, source electrode 111 shown in FIG. 13 is formed as follows. Specifically, a resist film having a pattern is formed on oxide film 126, using a photolithography method. Using this resist film as a mask, a portion of oxide film 126, which is located on source region 124 and contact region 125, is etched away. An opening portion 126a is thus formed in oxide film 126. For example, a conductor film is formed in this opening portion 126a in contact with each of source region 124 and contact region 125, for example, with an evaporation method. Then, by removing the resist film, removal (lift-off) of a portion of the conductor film above, that has been located on the resist film, is carried out. This conductor film may be implemented by a metal film and it is composed, for example, of nickel (Ni). As a result of this lift-off, source electrode 111 is formed.

It is noted that heat treatment for alloying is preferably performed here. For example, in an atmosphere of an argon (Ar) gas representing an inert gas, heat treatment for 2 minutes at a heating temperature of 950° C. is performed.

Thereafter, as shown in FIG. 10, upper source electrode 127 is formed on source electrode 111, for example, with an evaporation method. In addition, drain electrode 112 is formed on the back surface of SiC substrate 2, for example, with an evaporation method.

Further, gate electrode 110 is formed, for example, as follows. A resist film having an opening pattern located in a region above oxide film 126 is formed in advance and an electric conductor film implementing a gate electrode is formed to cover the entire surface of the resist film. Then, by removing the resist film, the electric conductor film other than a portion of the electric conductor film to serve as the gate electrode is removed (lifted off). Consequently, as shown in FIG. 10, gate electrode 110 can be formed on oxide film 126.

By performing the steps (steps S1 to S8) above, MOSFET 102 representing the SiC semiconductor device shown in FIG. 10 can be manufactured.

It is noted that a configuration in which conductive types are interchanged in the present embodiment, that is, a configuration in which p-type and n-type are interchanged, may also be employed.

Though SiC substrate 2 is employed for fabricating MOSFET 102, a material for the substrate is not limited to SiC and it may be fabricated with the use of crystal of other materials. Alternatively, SiC substrate 2 may not be provided.

As described above, MOSFET 102 representing one example of the SiC semiconductor device in the present embodiment includes epitaxial layer 101 having surface 101a of which metal surface density is not higher than 1×10¹² cm⁻² and oxide film 126 formed on this surface 101a.

Metal surface density of surface 101a of epitaxial layer 101 is decreased to 1×10¹² cm⁻² or lower by forming oxide film 3 (see FIG. 9) in a dry atmosphere at a temperature not lower than 700° C. that contains O atoms and then removing oxide film 3. By forming oxide film 126 constituting the SiC semiconductor device on this surface 101a to thereby fabricate the SiC semiconductor device (in the present embodiment, MOSFET 102), characteristics such as a reverse breakdown voltage of oxide film 126 can be improved and an impurity, particles or the like present at the interface between surface 101a and oxide film 3 and in oxide film 3 can be reduced. Therefore, a reverse breakdown voltage of MOSFET 102 at the time of application of a reverse voltage can be improved. In addition, traps present at the interface between surface 101a of epitaxial wafer 101 and oxide film 126 (also referred to as interface state or interface state density) can be reduced. Thus, in a region of epitaxial wafer 101 opposed to oxide film 126, many carriers to serve as an inversion channel layer can be prevented from being trapped in the interface state. Moreover, trapped carriers can be prevented from behaving as fixed charges. Therefore, many of the carriers can contribute to a source-drain current while a voltage applied to the gate electrode (a threshold voltage) can be maintained low. Channel mobility can thus be improved. Therefore, stability and long-time reliability of an operation at the time of application of a forward voltage can be improved. Characteristics of the SiC semiconductor device can thus be improved.

Though a MOSFET has been described by way of example of an SiC semiconductor device in the present embodiment, the SiC semiconductor device according to the present invention is applicable also to a semiconductor device having an insulating gate type electric field effect portion such as an IGBT, a JFET, and the like.

### EXAMPLES

In a present Example, an effect of forming an oxide film in a dry atmosphere at a temperature not lower than 700° C. that contains O atoms was examined.

In the present Example, a surface 130a of an epitaxial wafer 130 representing an SiC semiconductor shown in FIG. 14 was cleaned. It is noted that FIG. 14 is a cross-sectional view schematically showing epitaxial wafer 130 cleaned in Example.

Specifically, initially, a 4H—SiC substrate having surface 1a was prepared as SiC substrate 1 (step Si).

Then, a p-type SiC layer 131 having a thickness of 10 μm and impurity concentration of 1×10¹⁶ cm⁻³ was grown with the CVD method as a layer implementing epitaxial layer 120 (step S4).

Then, using SiO₂ as a mask and using phosphorus (P) as an n-type impurity, source region 124 and a drain region 129 having impurity concentration of 1×10¹⁹ cm⁻³ were formed. In addition, using aluminum (Al) as a p-type impurity, contact region 125 having impurity concentration of 1×10¹⁹ cm⁻³ was formed (step S5). It is noted that the mask was removed after implantation of each ion.

Then, activation annealing treatment was performed. In this activation annealing treatment, an Ar gas was employed as an atmospheric gas, and such conditions as a heating temperature from 1700 to 1800° C. and a heating time period of 30 minutes were set. Epitaxial wafer 130 having surface 130a was thus prepared.

Then, surface 130a of epitaxial wafer 130 was subjected to acid cleaning with the use of SPM. Thus, removal of an organic substance on surface 130a was confirmed.

Then, epitaxial wafer 130 was immersed in HF. Thus, removal of a natural oxide film on surface 130a was confirmed.

Then, epitaxial wafer 130 was introduced into an oxidation furnace, and surface 130a of epitaxial wafer 130 was subjected to heat treatment for 1 hour in a dry atmosphere at a temperature of 1200° C. that contained 100% oxygen (step S2). Thus, formation of an oxide film having a thickness of 100 nm on surface 130a of epitaxial wafer 130 was confirmed.

Then, epitaxial wafer 130 was immersed in HF. Thus, removal of the oxide film (step S3) formed in step S2 was confirmed.

Through the steps (steps S1 to S5) above, surface 130a of epitaxial wafer 130 was cleaned. Metal surface density of cleaned surface 130a was measured with total X-ray reflection fluorescence (TXRF). Then, it was confirmed that metal surface density at the surface of the epitaxial wafer was not higher than 1×10¹⁰ cm⁻². Metal surface density at the surface of the cleaned epitaxial wafer was lower than metal surface density of the epitaxial wafer before cleaning.

From the foregoing, according to the present Example, it was found that an oxide film can be formed on the surface of the SiC semiconductor by forming the oxide film in a dry atmosphere at a temperature not lower than 700° C. that contains oxygen atoms. In addition, it was found that a metal impurity or the like deposited onto the surface can be reduced by forming an oxide film on the surface of the SiC semiconductor and removing this oxide film. Further, it was found that metal surface density at the surface can be not higher than 1×10¹⁰ cm⁻² by using the cleaning method according to the present invention.

Though the embodiments and the examples of the present invention have been described as above, combination of the features in each embodiment and example as appropriate is also originally intended.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A method of cleaning a silicon carbide semiconductor, comprising the steps of:
forming an oxide film on a surface of a silicon carbide semiconductor; and
removing said oxide film, and
in said forming step, said oxide film being formed in a dry atmosphere at a temperature not lower than 700° C. that contains oxygen atoms.

2. The method of cleaning a silicon carbide semiconductor according to claim 1, wherein
said dry atmosphere has oxygen concentration not lower than 1% and not higher than 100%.

3. The method of cleaning a silicon carbide semiconductor according to claim 1, wherein
said dry atmosphere contains water vapor.

4. The method of cleaning a silicon carbide semiconductor according to claim 1, wherein
in said removing step, said oxide film is removed with hydrogen fluoride.

5. The method of cleaning a silicon carbide semiconductor according to claim 1, wherein
in said forming step, said oxide film having a thickness not smaller than one molecular layer and not greater than 30 nm is formed.

6. A silicon carbide semiconductor having a surface, and
said surface having metal surface density not higher than 1×10¹² cm⁻².

7. A silicon carbide semiconductor device, comprising:
the silicon carbide semiconductor according to claim 6; and
an oxide film formed on said surface of said silicon carbide semiconductor.
